(19) United States
(12) Patent Application Publication
(10) Pub. No.: US 2009/0017314 A1
(43) Pub. Date: Jan. 15, 2009

(54) METHOD FOR DEPOSITION OF AN ANTI-SCRATCH COATING

(75) Inventors: Nicolas Nadaud, Paris (FR); Andriy Kharchenko, Palaiseau (FR)

Correspondence Address: OBLON, SPIVAK, MCCLELLAND MAIER & NEUSTADT, P.C., 1940 DUKE STREET, ALEXANDRIA, VA, 22314, US

(73) Assignee: Saint-Gobain Glass France, Courbevoie (FR)

(21) Appl. No.: 11/997,323

(22) PCT Filed: Jul. 26, 2006
(86) PCT No.: PCT/FR06/50750

§ 371 Date: Jul. 28, 2008

(30) Foreign Application Priority Data
Aug. 1, 2005 (FR) 0552404

(51) Int. Cl. C23C 14/34; B32B 9/04; B32B 15/04

(52) U.S. Cl. 428/446; 204/192.11; 428/469; 428/698; 428/702

(57) ABSTRACT

Process for the vacuum deposition of at least one boron-based thin film on a substrate, characterized in that:
at least one sputtering species that is chemically inactive or active with respect to boron is chosen;
a collimated beam of ions comprising predominantly said sputtering species is generated using at least one linear ion source positioned within an installation of industrial size;
said beam is directed onto at least one boron-based target; and
at least one surface portion of said substrate facing said target is positioned in such a way that said material sputtered by the ion bombardment of the target or a material resulting from the reaction of said sputtered material with at least one of the sputtering species is deposited on said surface portion.

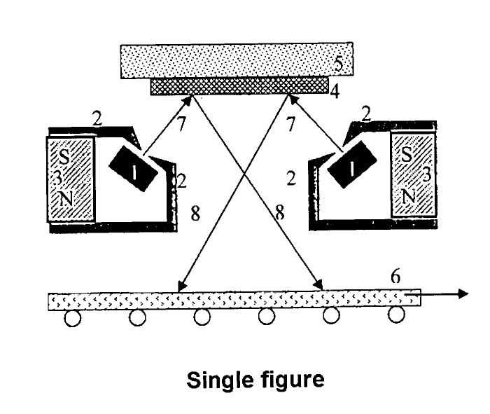

The present invention relates to a process of depositing thin films having scratch-resistant or surface-reinforcing functionalities onto a substrate, especially a glass substrate. It relates more particularly to the processes of deposition that are intended to be integrated into a vacuum deposition installation for depositing films for example (but not exclusively) on architectural glass, these installations being of industrial size (for a substrate having a dimension perpendicular to the direction of travel of greater than 1.5 m, or even 2 m). The invention also applies to substrates coated with a multilayer providing various (solar control, low-emissivity, electromagnetic shielding, heating, hydrophilic, hydrophobic, photocatalytic) functionalities, said films modifying the level of reflection in the visible (antireflection or mirror films operating in the visible or solar infrared range) incorporating an active (electrochromic, electroluminescent, photovoltaic, piezoelectric, scattering, absorbent) system.

This is because, for all these substrates, it may be advantageous to improve their scratch resistance, scratches possibly resulting from a very wide range of situations:
(i) scratching by point contact with an object of higher hardness than the glass: scratching by rubbing or vandalism (glass for urban furniture), scratching by contact with a tool or glass holder, etc. during conversion steps (for example double-glazing or lamination steps); and
(ii) abrasion by fine particles (for example sand). The substrate then has a milky appearance, caused by light scattering, as a result of a high level of microdamage. This is particularly the case for substrates intended for automobiles (for example windshields).

This improvement in scratch resistance may be achieved by treating one or both sides of the substrate in contact with the environment or coated with a film, or it may be achieved by treating a substrate precoated with one or more thin films providing another functionality (such as for example one of those mentioned above). Typically, the reinforcing film is then referred to as an “overcoat” in that it has a very small thickness and chronologically completes the sequence of deposition of all of the films.

Films having a scratch-resistance functionality, whether they are deposited directly on one of the bare sides of the substrate, or deposited as an overcoat on a multilayer already deposited, are produced in a known manner using conventional thin-film deposition processes of the plasma or magnetron sputtering type, the thin films obtained possibly being based on DLC (Diamond-Like Carbon) (the reader may refer to patent EP 1 177 156) or based on a mixed tin zinc antimony oxide (SnₓZn_{y}Sb₂O_{w}) (the reader may refer to patent application EP 1 042 247). It is particularly economic to use a process for depositing the mechanical reinforcement film that is compatible technologically speaking with the process for depositing the multilayer.

These deposition techniques are entirely satisfactory for this type of film but they each have their drawbacks to which the present invention proposes to provide a solution.

Thus, the DLC film obtained by a plasma deposition technique has a high absorption in the visible, this being prejudicial to the production of multilayer transmission glazing (brown coloration in transmission, considered to be unattractive and limiting the amount of light transmitted through the glazing) and greatly limiting the use of such a film within a multilayer operating in the visible. As regards a film based on a mixed tin zinc antimony oxide deposited by magnetron sputtering, this has scratch-resistant properties that are better than those of the overcoats known from the prior art, but said properties may be further improved by depositing a film based on boron nitride.

This is because it is known that boron nitride films may exhibit advantageous mechanical properties when they are crystallized in particular phases:
hexagonal or graphitic phase (sp2 hybridization of boron) a priori of mediocre hardness, but having a low friction coefficient; and
cubic phase (sp3 hybridization) of high hardness (50 GPa).

Films based on boron nitride have the uncommon feature of exhibiting mechanical properties such as those described above combined with good transparency in the visible (E_{g}˜4 to 6 eV) and a refractive index (1.6 to 2.2 depending on the crystallographic phase) compatible with the materials deposited as thin films elsewhere.

Varieties of hexagonal and cubic structure are chemically very inert, especially with respect to high-temperature oxidation. The graphitic variety for example is resistant up to 1200° C. and particularly resistant up to 700° C., the usual temperature for the forming, bending and toughening treatments carried out on flat glass.

However, the industrial production of such BN thin films (of cubic structure denoted by cBN or hexagonal structure denoted by hBN) on large substrates (critical size >1.5 m) has a few drawbacks:
the targets that can be used are electrically insulating (boron, amorphous boron nitride, hexagonal boron nitride), thereby requiring the use of an RF (radiofrequency) bias (for example at 13.56 MHz) which is not very compatible with the abovementioned critical substrate size). This is because magnetron sputtering cannot be used in a uniform manner on cathodes greater than two meters in length (for deposition on substrates of similar specific dimensions) except if the bias, for example sinusoidal or pulsed, is at a frequency, the corresponding wavelength of which is very long compared with the length of the cathode. Thus, it is notoriously difficult to achieve uniform deposition using a cathode more than 3 m in length and with radiofrequency sputtering (at about 13.56 MHz); and
the use of a PECVD (Plasma Enhanced Chemical Vapor Deposition) technique is also tricky since, apart from the need for RF biasing, it does not allow the thickness uniformity of the deposited films to be controlled with sufficient acuity (a few A or a few nm).

The object of the present invention is therefore to alleviate the drawbacks of magnetron sputtering deposition processes by proposing a compatible deposition process that permits a boron-based thin film to be deposited.

For this purpose, the process for the vacuum deposition of at least one boron-based thin film on a substrate is characterized in that:
at least one sputtering species that is chemically inactive or active with respect to boron is chosen;
a collimated beam of ions comprising predominantly said sputtering species is generated using at least one linear ion source positioned within an installation of industrial size;
said beam is directed onto at least one boron-based target; and
at least one surface portion of said substrate facing said target is positioned in such a way that said material sputtered by the ion bombardment of the target or a material resulting from the reaction of said sputtered material with at least one of the sputtering species is deposited on said surface portion.

Thanks to these arrangements, it is possible, on the one hand, to obtain a thin film of a compound material, at least one of the cations of which is contained in an electrically conducting or insulating target and, on the other hand, to deposit particularly at least one thin film containing predominantly boron on a surface portion of a substrate in a thin-film deposition installation, this installation being of industrial size and operating in a vacuum.

In preferred methods of implementing the invention, one or more of the following arrangements may optionally be also employed:
an operation of causing relative movement between the ion deposition source and the substrate is carried out;
the linear ion source generates a collimated ion beam with an energy between 0.2 and 10 keV, preferably between 1 and 5 keV and especially about 1.5 keV;
an operation for taking the pressure in the installation into a range between 10⁻⁵ and 8×10⁻³ torr is carried out;
the ion beam and the target make between them an angle α of between 90° and 30°, preferably between 60° and 45°;
the material to be sputtered using at least said linear ion deposition source is deposited, on two different surface portions of a substrate simultaneously or in succession;
the material sputtered using at least said linear ion deposition source is deposited on at least one bare surface portion of a substrate;
the material sputtered using at least said linear ion deposition source is deposited on at least one substrate portion at least partly coated with at least one other film;
an additional species is introduced as a complement to said sputtering species, said additional species being chemically active with respect to said sputtered material;
the additional species is obtained by an injection of gas incorporating said additional species, for example near the substrate;
the additional species that is injected comprises nitrogen or argon, used by itself or possibly as a mixture with a minor fraction of CH₄ and/or H₂;
a target comprising a material chosen from the following family is used: amorphous boron, boron crystallized in cubic form, boron crystallized in hexagonal form, aluminum, silicon, amorphous boron nitride, boron nitride crystallized in hexagonal form, boron nitride crystallized in cubic form, silicon nitride, aluminum nitride and a mixed nitride of at least these materials, this material being used by itself or as a mixture;
the target is biased so as to adjust the energy of the sputtering species;
the biased target is fastened to a cathode magnetron;
an ion-neutralizing device is positioned nearby, possibly consisting of a cathode magnetron placed nearby or an electron injector (a thermionic emission device in the form of a filament for example); and
a second ion source, the ion beam of which is focused onto the substrate, is used.

According to another aspect of the invention, this also relates to a substrate, especially a glass substrate, at least one surface portion of which is coated with a thin-film multilayer that includes at least one film based on a material chosen from the following family: amorphous boron nitride, boron nitride crystallized in hexagonal form, boron nitride crystallized in cubic form, silicon nitride, aluminum nitride and a mixed nitride of at least these materials, this material being used by itself or as a mixture.

The present invention will be more clearly understood on reading the following detailed description of nonlimiting illustrative examples and on examining the single appended FIGURE.

The single FIGURE shows an ion deposition source in a chamber of industrial size. A substrate bearing the numerical reference 6 runs through the chamber, and in particular this substrate is coated with a sputtered material 8 resulting from the sputtering by a collimated ion beam 6 on a target 1. The ion source is provided with a cathode 3, 4, an anode 5 and magnets 2 enables the ion beam to be confined.

In a preferred method of implementing the process according to the invention, this consists in inserting, into a line of industrial size (typically a line width of about 3.5 m), for depositing thin films on a substrate, at least one linear ion deposition source (refer to the single FIGURE). For the purpose of the invention, the expression “of industrial size” is understood to mean a production line whose size is designed, on the one hand, to operate continuously and, on the other hand, to treat substrates in which one of the characteristic dimensions, for example the width perpendicular to the direction of travel of the substrate, is at least 1.5 m.

For the purpose of the invention, the expression “ion deposition source” is understood to mean a complete system integrating a linear ion source and a device integrating a target and a target holder.

This linear ion deposition source is positioned within a treatment chamber, the working pressure of which may be easily lowered to below 0.1 mtorr (about 133×10⁻⁴ Pa) and in practice 1×10⁻⁵ to 5×10⁻³ torr. This working pressure may generally be 2 to 50 times lower than the lowest working pressure for a magnetron sputtering line, but the linear ion deposition device may also operate at the deposition pressure of the conventional magnetron process.

By means of an ion source as shown in the single FIGURE, and using the following deposition conditions:
-40.0 cm target made of hBN; 0.75 mtorr deposition pressure; gas flow rates: 10 sccm of Ar and 2 sccm of N₂, the source having a power of 70 W,
   the hBN material was sputtered onto a bare substrate (glass sold by the Applicant under the trademark Planilux®, this glass having a thickness of 2 mm) and the multilayer of Example 1 was obtained.

### EXAMPLE 1

### Glass (2 mm)/hBN (10 nm)

The multilayer shown below as Example 2 corresponded to a standard multilayer of the low-emissivity type from the Applicant company:

### EXAMPLE 2

### Glass/Si₃N₄/ZnO/NiCr Ag/ZnO/Si₃N₄

Using deposition conditions similar to Example 1, an hBN film was deposited on the multilayer of Example 2 so as to obtain the multilayer structure of Example 3:

### EXAMPLE 3

### Glass/Si₃N₄/ZnO/NiCr/Ag/ZnO/Si₃N₄/hBN (4 nm)

The table below gives the optical characteristics.

| | T_{L} (%) | R_{L} (%) | Absorption (%) |
|---|---|---|---|
| Float glass (reference | 90.53 | 8.39 | 1.08 |
| example) | | | |
| Example 1 | 90.23 | 8.45 | 1.32 |
| Glass/low-E (Example 2) | 82.1 | 4.3 | 13.6 |
| Glass/low-E/BN (Example 3) | 82.4 | 4.2 | 13.4 |

As may be seen in this table, the boron nitride hardly modifies the optical properties, the values of T_{L} (%), R_{L} (%) and absorption (%) are not modified or only slightly modified when, on the one hand, the reference example is compared with Example 1 and, on the other hand, the values of Example 2 and Example 3 are compared.

As the measured values of the friction coefficient given in the table below illustrate, the hBN film is lubricating (the friction coefficient is reduced by substantially a factor of 2 between, on the one hand, the reference example and Example 1 and, on the other hand, between Example 2 and Example 3).

The friction coefficient was measured using a linear reciprocating tribometer. The contact was of the pin-on-disk type with a run speed between 10 μm/s and 10 mm/s (preferably of the order of 1 mm/s) and an applied normal force of between 0.1 N and 20 N (preferably 3 N). The measurement was obtained in air at ambient temperature.

| | Glass | | | Glass/low- |
|---|---|---|---|---|
| | (reference | Glass/BN | Glass/low-E | E/BN |
| | example) | (Example 1) | (Example 2) | (Example 3) |
| Friction | 0.8 | 0.4 | 1.5 | 0.6 |
| coefficient | | | | |

Whatever the example, at least one linear ion deposition source is used, the operating principle of which is as follows.

The linear ion source comprises, very schematically, an anode, a cathode, a magnetic device and a gas injection source. Examples of this type of source are described in particular in RU 2 030 807, U.S. Pat. No. 6,002,208 and WO 02/093987. The anode is raised to a positive potential by a DC power supply, the potential difference between the anode and the cathode causing a gas injected nearby to be ionized. In this case, the gas injected may be a mixture of gases based on oxygen, argon, nitrogen, helium or a noble gas, such as for example also neon, or a mixture of these gases.

The gas plasma is then subjected to a magnetic field (generated by permanent magnets or nonpermanent magnets), thereby accelerating and focusing the ion beam. The ions are thus collimated and accelerated out of the source toward at least one optionally biased target that it is desired to sputter with the material, the beam current being dependent in particular on the geometry of the source, on the gas flow rate, on the nature of the gas and on the voltage applied to the anode. In particular, the operating parameters for the ion deposition source are adapted so that the energy and the acceleration transmitted to the collimated ions are sufficient to sputter, owing to their mass and their sputtering cross section, aggregates, of the material forming the target.

The respective orientation of the ion source(s) and the target is such that the ion beam(s) ejected from the source sputters the target at one or more predetermined mean angles (between 90° and 30°, preferably between 60° and 45°). The vapor of sputtered atoms must be able to reach a moving substrate whose width is at least 1 meter (1.5 m being the critical size above which an installation may be termed an industrial installation). As a variant, the target may be integrated into a magnetron sputtering device.

Optionally, it is possible to inject, near the substrate, by means of a gas injection device, a second species in the form of gas or a plasma, which is chemically active with respect to the sputtered or bombarded material coming from the target.

It is possible to integrate several sources within a production line, it being possible for the sources to operate on the same side of a substrate or on both sides of a substrate (for example in a sputter-up/sputter-down line), either simultaneously or consecutively.

Thus, a linear ion source generating collimated ions may be introduced into a conventional treatment (magnetron sputtering) chamber that can operate in sputter-up mode (sputtering from above) and/or sputter-down mode (sputtering from below).

The ion source is introduced instead of a sputter-up cathode so as to produce a multilayer of diverse functionality by sputtering-down on the front side of the glass and, at the end of the deposition process, a scratch-resistant film on the rear side of the glass (similar to the deposition in Example 1), this rear side being the side that has to be exposed to the weather. It is also possible, simultaneously with the process described here, to deposit a protective overcoat based on boron after the multilayer has been deposited on the front side by a sputter-down process (especially Example 3).

The mechanically reinforcing scratch-resistant character of the film results from the lubricating properties of said film.

It is also possible to equip the linear ion deposition source with an ion-neutralizing device (a thermionic electron emission source, for example in the form of a filament) so as to prevent the target from charging up and arcs from appearing in the deposition chamber. This device may consist of a plasma, for example coming from a cathode magnetron operating nearby.

The substrates on the surface of which the abovementioned thin films are deposited are preferably transparent, whether flat or curved, made of glass or plastic (PMMA, PC, etc.).

Even more generally, the process according to the invention makes it possible to produce, in a chamber of industrial size, a substrate, especially a glass substrate, having, on at least one of its sides, a thin-film multilayer that includes at least one film deposited (either on a bare face of the substrate or on a thin-film multilayer deposited beforehand on the substrate) by said process and the scratch resistance of which has been improved compared with a protective film deposited by magnetron sputtering.

To summarize, the process according to the invention allows a film having a lubricating functionality to be deposited on at least a bare surface of a substrate having a glass function or on a multilayer of diverse functionality already deposited on at least one substrate portion.

According to a first type of substrate, especially a glass substrate, is coated on at least one surface portion with a thin-film multilayer comprising an alternation of n functional layers A having reflection properties in the infrared and/or in solar radiation, based especially on silver, and of (n+1) coatings B where n≧1, said coatings B comprising a film or a superposition of films made of a dielectric based especially on silicon nitride or on a mixture of silicon and aluminum, or on silicon oxynitride, or on zinc oxide, or on tin oxide or on titanium oxide, in such a way that each functional film A is placed between two coatings B, the multilayer also including at least one metal layer C in the visible, especially based on titanium, nickel-chromium or zirconium, said films possibly being in nitride or oxide form and being located above and/or below the functional film, the terminal film of the multilayer then being covered with a film providing a scratch-resistance functionality.

According to a second type of substrate, especially a glass substrate, is coated on at least one surface portion with an antireflection or mirror coating operating in the visible or solar infrared range, made from a multilayer (A) of thin films made of dielectrics having alternately high and low refractive indices, the terminal film of the multilayer then being covered with a film providing a scratch-resistance functionality.

These substrates thus coated form glazing assemblies intended for applications in the automobile industry, especially an automobile sunroof, a side window, a windshield, a rear window, a wing mirror or a rear-view mirror, or a single or double glazing unit intended for buildings, especially an indoor or outdoor window for buildings, or a showcase, store counter, possibly curved, or glazing for protecting an article of the painting type, or an antidazzle screen for a computer, glass furniture, a glass parapet or an antisoiling system.

1: A process for the vacuum deposition of at least one boron-based thin film on a substrate, comprising:
at least one sputtering species that is chemically inactive or active with respect to boron is chosen;
a collimated beam of ions comprising predominantly said sputtering species is generated using at least one linear ion source positioned within an installation of industrial size;
said beam is directed onto at least one boron-based target; and
at least one surface portion of said substrate facing said target is positioned in such a way that a material sputtered by the ion bombardment of the target or a material resulting from a reaction of said sputtered material with at least one of the sputtering species is deposited on said surface portion.

2: The process as claimed in claim 1, wherein an operation of causing relative movement between the ion deposition source and the substrate is carried out.

3: The process as claimed in claim 1, wherein the linear ion source generates a collimated ion beam with an energy between 0.2 and 10 keV.

4: The process as claimed in claim 1, wherein an operation for taking the pressure in the installation into a range between 10⁻⁵ and 8×10⁻³ torr is carried out.

5: The process as claimed in claim 1, wherein the ion beam and the target have an angle α of between 90° and 30° between them.

6: The process as claimed in claim 1, wherein the material to be sputtered using at least said linear ion deposition source is deposited, on two different surface portions of a substrate simultaneously or in succession.

7: The process as claimed in claim 1, wherein the material sputtered using at least said linear ion deposition source is deposited on at least one bare surface portion of a substrate.

8: The process as claimed in claim 1, wherein the material sputtered using at least said linear ion deposition source is deposited on at least one substrate portion at least partly coated with at least one other film.

9: The process as claimed in claim 1, wherein an additional species is introduced as a complement to said sputtering species, said additional species being chemically active with respect to said sputtered material, the additional species being obtained by an injection of gas incorporating said additional species near the substrate.

10: The process as claimed in claim 9, wherein the additional species that is injected comprises nitrogen or argon, used by itself or possibly as a mixture with a minor fraction of CH₄ and/or H₂.

11: The process as claimed in claim 1, wherein the target comprises a material selected from the group consisting of amorphous boron, boron crystallized in cubic form, boron crystallized in hexagonal form, aluminum, silicon, amorphous boron nitride, boron nitride crystallized in hexagonal form, boron nitride crystallized in cubic form, silicon nitride, aluminum nitride and mixtures thereof.

12: The process as claimed claim 1, wherein the target is biased so as to adjust the energy of the sputtering species.

13: The process as claimed in claim 12, wherein the biased target is fastened to a cathode magnetron.

14: The process as claimed in claim 1, wherein an ion-neutralizing device is positioned nearby, optionally consisting of a cathode magnetron.

15: The process as claimed in claim 1, wherein a second ion source, the ion beam of which is directed onto the substrate, is used.

16: A substrate coated on at least one surface portion with a thin-film multilayer comprising an alternation of n functional layers A having reflection properties in the infrared and/or in solar radiation, and of (n+1) coatings B where n≧1, said coatings B comprising a film or a superposition of films made of a dielectric based on silicon nitride, a mixture of silicon and aluminum, silicon oxynitride, zinc oxide, tin oxide, or titanium oxide, in such a way that each functional film A is placed between two coatings B, the multilayer also including at least one metal layer C in the visible radiation, based on titanium, nickel-chromium or zirconium, said films optionally being in nitride or oxide form and being located above and/or below a functional film, wherein a final film of the multilayer is covered with at least one terminal film based on a material selected from the group consisting of amorphous boron nitride, boron nitride crystallized in hexagonal form, boron nitride crystallized in cubic form, silicon nitride, aluminum nitride and mixtures thereof, the terminal film being deposited by the process as claimed in claim 1.

17: A substrate coated on at least one surface portion with an antireflection or mirror coating operating in the visible or solar infrared range, made from a multilayer (A) of thin films made of dielectrics having alternately high and low refractive indices, wherein a final film of the multilayer is covered with at least one terminal film based on a material selected from the group consisting of amorphous boron nitride, boron nitride crystallized in hexagonal form, boron nitride crystallized in cubic form, silicon nitride, aluminum nitride and mixtures thereof the terminal film being deposited by the process as claimed in claim 1.

18: A substrate comprising at least one film based on a material selected from the group consisting of amorphous boron nitride, boron nitride crystallized in hexagonal form, boron nitride crystallized in cubic form, silicon nitride, aluminum nitride and mixtures thereof, said film being deposited by the process as claimed in claim 1.

19: The substrate as claimed in claim 16, wherein a substrate is intended for the automobile industry, for buildings, for protecting an article of a painting type, or for antidazzle screen and glass furniture, optionally incorporating a photovoltaic system, a display screen, a glass parapet or an antisoiling system.
